(19) United States
(12) Patent Application Publication
(10) Pub. No.: US 2016/0126194 A1
(43) Pub. Date: May 5, 2016

(54) MEASUREMENT MARK STRUCTURE AND MANUFACTURING METHOD THEREOF

(71) Applicant: UNITED MICROELECTRONICS CORP., Hsin-Chu City (TW)

(72) Inventors: Chia-Chang Hsu, Kaohsiung City (TW); Teng-Chin Kuo, Taipei (TW); En-Chiuan Liou, Tainan City (TW)

(21) Appl. No.: 14/533,108

(22) Filed: Nov. 5, 2014

(51) Int. Cl. H01L 23/544; H01L 21/311; G01B 11/00

(52) U.S. Cl. CPC H01L 23/544; G01B 11/002; H01L 21/311; H01L 2223/54426

(57) ABSTRACT

The present invention provides a measurement mark structure, including a plurality of inner patterns, the inner patterns being arranged along a first direction, and an outer pattern, positioned surrounding the inner patterns, and the outer pattern is rectangular frame shaped.

### BACKGROUND OF THE INVENTION

1. Field of the Invention

The invention relates to a measurement mark structure and manufacturing method thereof, and more particularly, to a measurement mark structure which can remedy the edge rough problem.

2. Description of the Prior Art

Photolithography is one of the most critical steps in semiconductor manufacturing processes. Due to the trend toward shrinking the dimensions of the semiconductor devices for improving performance and reducing cost, the key consideration of the photolithography process is not only the critical dimension, but also the alignment accuracy. In the case that the alignment accuracy is imprecise, the circuit patterns may not be connected to the circuit patterns in pre- or successive layers and result in failure of the device or the whole integrated circuit (IC). The alignment accuracy measurement is therefore taken as one of the most important measurements in the semiconductor manufacturing processes. And thus alignment measurement marks and/or overlay measurement marks are always formed on the wafers and the various material layers in order to improve the alignment accuracy.

However, it is observed that patterns or structures of the measurement marks themselves also affect the result of alignment accuracy measurement. For example, in the fin field effect transistor (hereinafter abbreviated as FinFET) process, edge roughness often occurs at the overlay measurement marks, which are formed simultaneously with forming the fin layers for accommodating the sources/drains. The edge roughness issue causes severe measurement deviation when the overlay measurement marks are scanned, and thus the result of alignment accuracy measurement is adversely impacted.

### SUMMARY OF THE INVENTION

The present invention provides a measurement mark structure, comprising: a plurality of inner patterns, the inner patterns being arranged along a first direction, and an outer pattern, positioned surrounding the inner patterns, and the outer pattern is rectangular frame shaped.

The present invention further provides a method for forming a measurement mark structure, at least comprising the following steps: first, a substrate is provided, and at least one mandrel pattern is formed on the substrate, next, a plurality of holes are formed in the mandrel pattern, and the holes are arranged along a first direction, afterwards, a spacer is formed on the sidewall of the mandrel pattern and in each hole, next the mandrel pattern is removed, the remained spacer defines a measurement mark structure, wherein the measurement mark structure comprises a plurality of inner patterns, the inner patterns are arranged along a first direction, and an outer pattern, positioned surrounding the inner patterns, and the outer pattern is rectangular frame shaped.

According to the present invention, one outer pattern is always positioned surrounding any given inner pattern, which is a practical and meaningful structure in the alignment accuracy measurement, no matter in the X-direction and/or the Y-direction. The outer pattern remedies the edge rough problem, and thus alignment accuracy measurement is improved. Furthermore, the measurement mark structure provided by the present invention can be not only integrated in fin fabrication in the FinFET process, but also integrated in any semiconductor process involving fin-cutting process. Accordingly, the measurement mark structure provided by the present invention provides superior process flexibility and applicability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic drawings illustrating a measurement mark structure provided by a first preferred embodiment of the present invention

FIG. 4 is a schematic drawing illustrating a measurement mark structure provided by a second preferred embodiment of the present invention.

FIG. 5 is a schematic drawing illustrating a modification to the second preferred embodiment.

### DETAILED DESCRIPTION

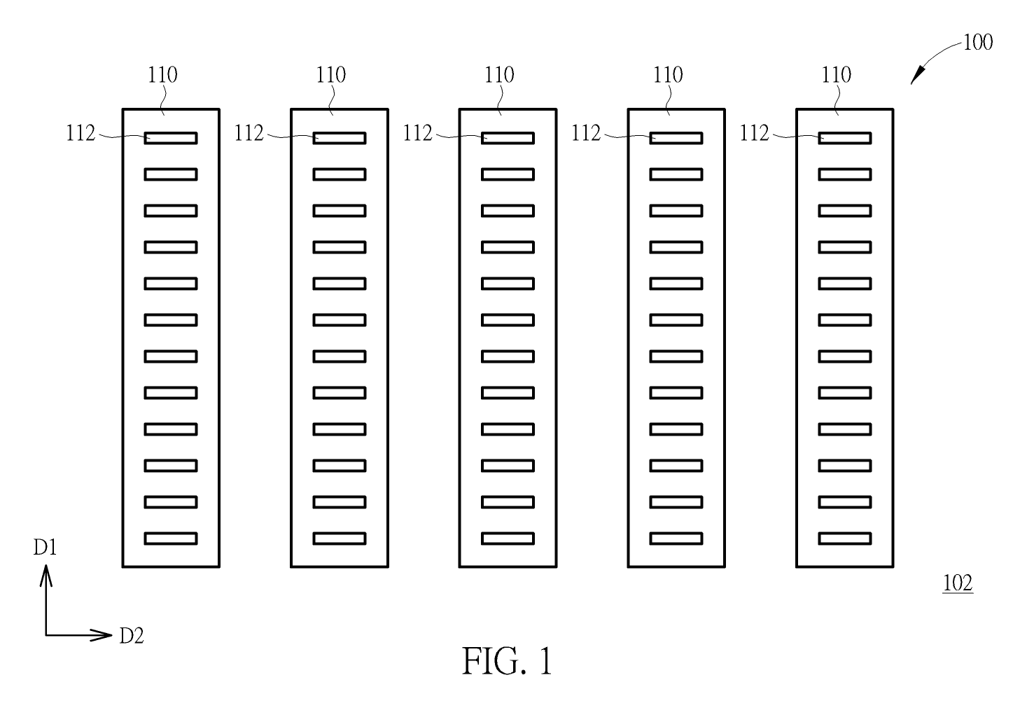

Please refer to FIGS. 1-3, which are schematic drawings illustrating a measurement mark structure provided by a first preferred embodiment of the present invention. As shown in FIG. 1, a measurement mark structure 100 provided by the preferred embodiment is formed by following steps. A substrate 102 is provided. Next, a plurality of mandrel patterns 110 and a plurality of holes 112 are formed in the mandrel patterns 110. It is well-known to those skilled in the art that the measurement mark structure is formed concurrently with forming a specific material layer/pattern or a specific device. Therefore alignment accuracy between the specific material layer/pattern and a pre-layer or a successive layer can be measured. In accordance with the preferred embodiment, the measurement mark structure 100 is formed along with fin layers of FinFET. Therefore, those skilled in the art would easily realize that a plurality of mandrel patterns (not shown) are formed in active regions in the substrate 102 simultaneously with forming the mandrel patterns 110 and the holes 112. Accordingly, the mandrel patterns 110 include polysilicon in the preferred embodiment, but not limited to this.

Please still refer to FIG. 1. The mandrel patterns 110 and the holes 112 both include strap shapes. It is also noteworthy that a size of the mandrel patterns 110 is much larger than a size of the holes 112. The mandrel patterns 110 are arranged along a second direction D2 and extended along a first direction D1, while the strap-shaped holes 112 are arranged along a first direction D1, and each strap-shaped hole 112 are extended along a second direction D2. As shown in FIG. 1, the first direction D1 and the second direction D2 are perpendicular to each other.

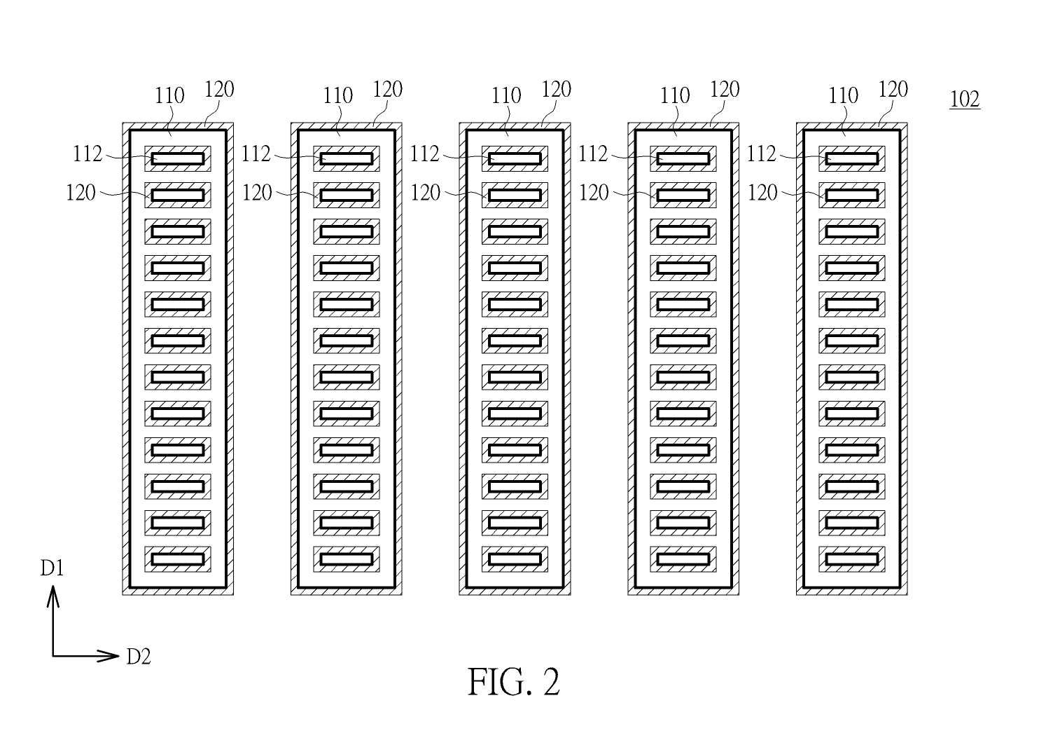

Please refer to FIG. 2. Next, a spacer layer (not shown) is formed on the substrate 102. The spacer layer can include silicon oxide, silicon nitride, silicon oxynitride and/or any suitable materials of which an etching rate is different from the mandrel patterns 110. Subsequently, an etching back process is performed on the spacer layer, and thus a spacer 120 is formed on sidewall of each mandrel pattern 110 and formed in each hole 112, in other words, the spacer 120 is formed on the outer sidewall of each mandrel pattern 110, and also formed on the inner sidewall of each mandrel pattern 110 (the edges of the holes 112) simultaneously. As mentioned above, since the measurement mark structure 100 is integrated in the FinFET process, and is used to measure the alignment accuracy between the fin layer and pre-/successive layers, a spacer is formed on sidewall of each mandrel pattern in the active regions of the substrate 102 simultaneously with forming the spacers 120.

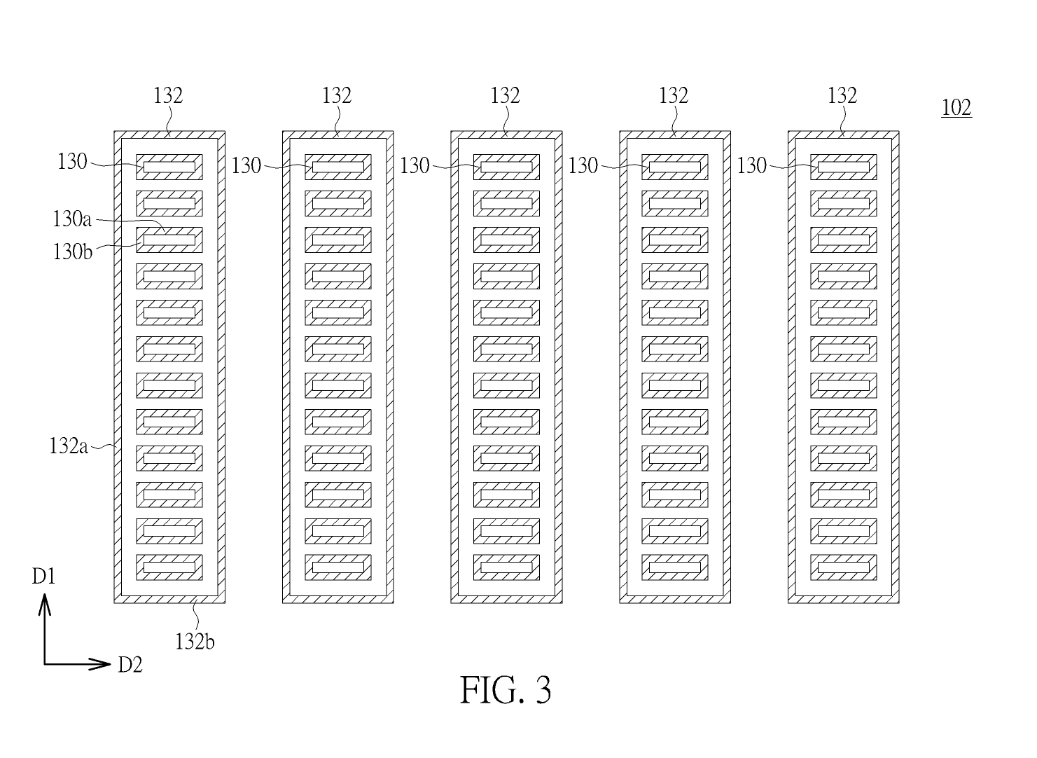

Please refer to FIG. 3. After forming the spacers 120, the mandrel patterns 110 are removed from the substrate 102. Consequently, only the rectangular frame shaped inner patterns 130 and the rectangular frame shaped outer patterns 132 remain on the substrate 102. And the inner patterns 130 and the outer patterns 132 construct the measurement mark structure 100 of the preferred embodiment. Simultaneously, the mandrel patterns in the active regions are removed and thus only the hollow ring-shaped spacers (not shown) are left in the active regions.

Please refer to FIG. 3 again. It is noteworthy that the measurement mark structure 100 provided by the preferred embodiment includes a plurality of inner patterns 130 and a plurality of outer patterns 132. One outer pattern 132 is positioned surrounding a plurality of inner patterns 130, but the outer pattern 132 does not contact each inner pattern 130 directly. The inner patterns 130 are rectangular frame shaped, arranged along the first direction D1, and each inner pattern 130 has two long edges 130a and two short edges 130b, wherein each long edge 130a of each inner pattern 130 is parallel to the second direction D2, and each short edge 130b of each inner pattern 130 is parallel to the first direction D1. And the outer patterns 132 is rectangular frame shaped too, extended along the first direction D1, each outer pattern 132 has two long edges 132a and two short edges 132b, wherein each long edge 132a of each outer pattern 132 is parallel to the first direction D1, and each short edge 132b of each outer pattern 132 is parallel to the second direction D2. As mentioned above, the first direction D1 and the second direction D2 are perpendicular to each other.

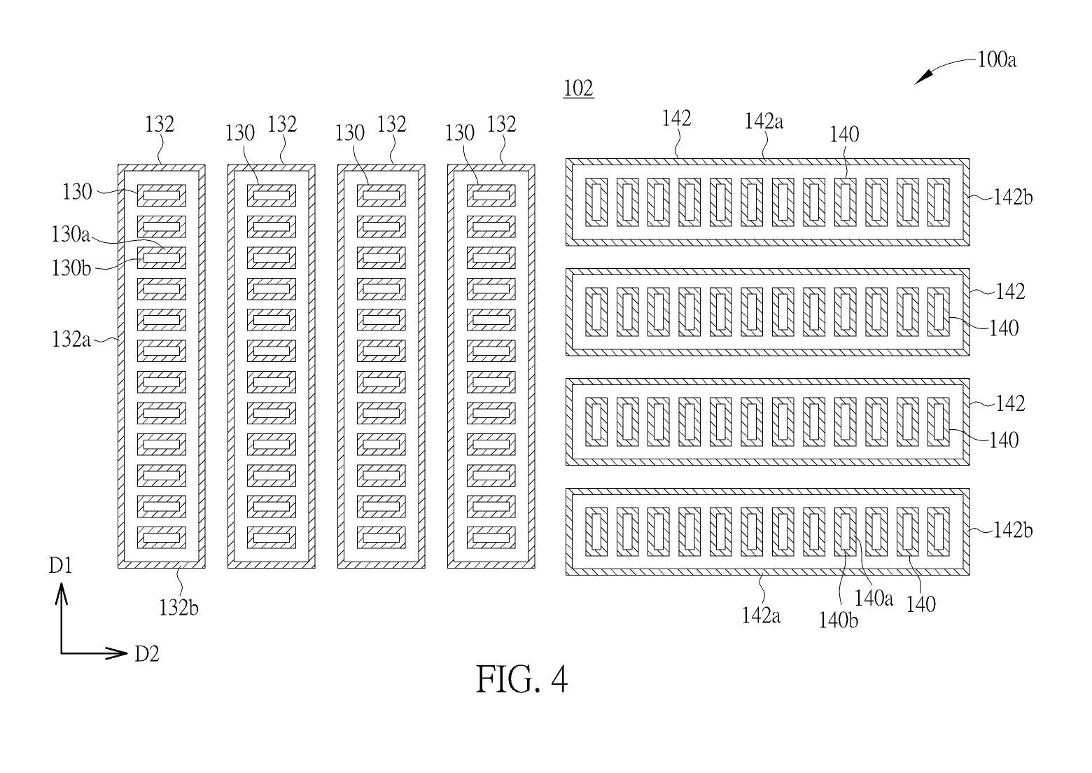

Please refer to FIG. 4, which is a schematic drawing illustrating a measurement mark structure provided by a second preferred embodiment of the present invention. It should be noted that elements that are the same in both of the first and second preferred embodiments are designated by the same numerals and formed on the substrate 102 by the same steps. Elements the same as in both of the first and second preferred embodiments also include the same arrangements. Therefore, those details are all omitted in the interest of brevity. The difference between the second and the first preferred embodiment is: The measurement mark structure 100a provided by the second preferred embodiment further includes a plurality of second inner patterns 140 and a plurality of second outer patterns 142 formed on the substrate 102. Each one of the second outer patterns 142 is disposed surrounding a plurality of second inner patterns 140 respectively.

The second inner patterns 140 are rectangular frame shaped, arranged along the second direction D2, and each second inner pattern 140 has two long edges 140a and two short edges 140b, wherein each long edge 140a of each second inner pattern 140 is parallel to the first direction D1, and each short edge 140b of each second inner pattern 140 is parallel to the second direction D2. And the second outer patterns 142 is rectangular frame shaped too, extended along the second direction D2, each second outer pattern 142 has two long edges 142a and two short edges 142b, wherein each long edge 142a of each second outer pattern 142 is parallel to the second direction D2, and each short edge 142b of each second outer pattern 142 is parallel to the first direction D1. As mentioned above, the first direction D1 and the second direction D2 are perpendicular to each other. Besides, the second inner pattern 140 does not contact the second outer pattern 142 directly.

In general, after the test pattern of the first layer and the test pattern of the second layer are formed on the substrate sequentially, an optical measuring method (such as photography) is then performed to determine the relative shift between the first layer and the second layer of the substrate in specific direction (such as in X-direction or in Y-direction). For example, the method includes comparing the test pattern edge of the first layer in X-direction and the test pattern edge of the second layer in X-direction, so as to determine the relative shift between the first layer and the second layer in X-direction. However, during the optical measuring method, the signal intensity contrast greatly influences the accuracy for determining the edges. Besides, if the pattern density of the measurement mark structure got increased, the measuring method will have better signal intensity contrast. In the present invention, the measurement mark structure comprises the inner patterns 130 and the outer patterns 132, the pattern density of the inner patterns 130 is higher than the pattern density of the outer patterns 132, so the inner patterns 130 has the better signal intensity contrast during the optical measuring method. But if the measurement mark structure of the present invention only comprises the inner patterns 130, the edge roughness will easily occurs. Therefore, the advantage of the present invention is combining the inner patterns 130 and the outer patterns 132 into one measurement mark structure, thereby increasing the signal intensity contrast but avoiding the edge roughness issue.

In the preferred embodiment, the first direction D1 is parallel with the Y-direction while the second direction D2 is parallel with the X-direction. Therefore, the preferred embodiment provides the inner patterns 130 arranged parallel with the Y-direction and the second inner patterns 140 arranged parallel with the X-direction. Also, the preferred embodiment provides the outer patterns 132 extended parallel with the Y-direction and the second outer patterns 142 extended parallel with the X-direction. More important, any given mark pattern 130/140 is surrounded in one outer patterns 132/142. Therefore, the edge roughness in both of the X-direction and the Y-direction are remedied due to the outer patterns 132/142 formed surrounding the inner patterns 130/140 in accordance with the preferred embodiment. Consequently, alignment accuracy measurement is improved.

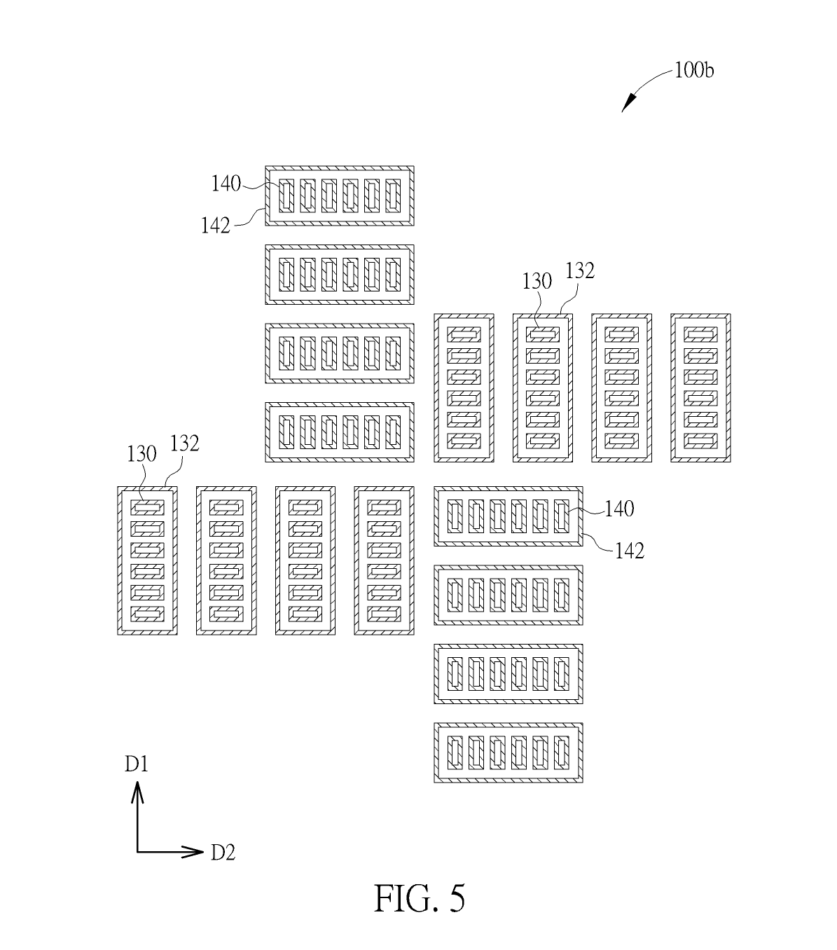

Please refer to FIG. 5, which is a schematic drawing respectively illustrating a modification to the second preferred embodiment. In this embodiment, the measurement mark structure 100b also comprises the inner patterns 130, the outer patterns 132, the second inner patterns 140 and the second outer patterns 142. But the inner patterns 130, the second inner patterns 140, the outer patterns 132 and the second outer patterns 142 are re-arranged. The other components, material properties, and manufacturing method of the measurement mark structure of this embodiment are similar to the first and the second preferred embodiments detailed above and will not be redundantly described.

It is well-known to those skilled in the art that alignment accuracy in the X-direction and the Y-direction are both required. Therefore the measurement mark structures 100a and 100b the second preferred embodiment and its modifications fulfill the requirement in both of the X-direction and the Y-direction by providing the inner patterns 130, the outer patterns 132, the second inner patterns 140 and the second outer patterns 142 in the X-direction and the Y-direction. Furthermore, by different arrangements and combinations of the inner patterns 130, the outer patterns 132, the second inner patterns 140 and the outer patterns 132, different structures can be achieved. That is, various measurement mark structures can be easily offered, and are not limited to those depicted in FIGS. 4-5. In other words, the preferred embodiment can easily provide the measurement mark structures fulfilling different requirements and the provided measurement mark structures always remedy the edge rough problem. Thus alignment accuracy measurement is improved.

According to the present invention, one outer pattern is always positioned surrounding any given inner pattern, which is a practical and meaningful structure in the alignment accuracy measurement, no matter in the X-direction and/or the Y-direction. The outer pattern remedies the edge rough problem, and thus alignment accuracy measurement is improved. Furthermore, the measurement mark structure provided by the present invention can be not only integrated in fin fabrication in the FinFET process, but also integrated in any semiconductor process involving fin-cutting process. Accordingly, the measurement mark structure provided by the present invention provides superior process flexibility and applicability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A measurement mark structure comprising:
a plurality of inner patterns, the inner patterns being arranged along a first direction; and
an outer pattern, positioned surrounding the inner patterns, and the outer pattern is rectangular frame shaped.

2. The measurement mark structure according to claim 1, wherein the outer pattern does not contact each inner pattern directly.

3. The measurement mark structure according to claim 1, wherein each inner pattern is rectangular frame shaped, and has two long edges and two short edges.

4. The measurement mark structure according to claim 3, wherein each long edge of each inner pattern is parallel to a second direction, wherein the second direction and the first direction are perpendicular to each other.

5. The measurement mark structure according to claim 4 further comprising:
a plurality of second inner patterns, and the second inner patterns being arranged along the second direction; and
a second outer pattern, positioned surrounding the second inner patterns, and the second outer pattern is rectangular frame shaped.

6. The measurement mark structure according to claim 5, wherein the second outer pattern does not contact each second inner pattern directly.

7. The measurement mark structure according to claim 1, wherein each outer pattern has two long edges and two short edges.

8. The measurement mark structure according to claim 7, wherein each long edge of each outer pattern is parallel to the first direction.

9. The measurement mark structure according to claim 1, further comprising a substrate, the inner patterns and the outer pattern being disposed on the substrate.

10. A method for forming a measurement mark structure, at least comprising the following steps:
providing a substrate, and at least one mandrel pattern is formed on the substrate;
forming a plurality of holes in the mandrel pattern, and the holes being arranged along a first direction;
forming a spacer on the sidewall of the mandrel pattern and in each hole; and
removing the mandrel pattern, the remained spacer defining a measurement mark structure, wherein the measurement mark structure comprises a plurality of inner patterns, the inner patterns being arranged along a first direction, and an outer pattern, positioned surrounding the inner patterns, and the outer pattern is rectangular frame shaped.

11. The method according to claim 10, wherein the outer pattern does not contact each inner pattern directly.

12. The method according to claim 10, wherein each inner pattern is rectangular frame shaped, and has two long edges and two short edges.

13. The method according to claim 12, wherein each long edge of each inner pattern is parallel to a second direction, wherein the second direction and the first direction are perpendicular to each other.

14. The method according to claim 10, further comprising:
forming a plurality of second inner patterns, and the second inner patterns being arranged along the second direction; and
forming a second outer pattern, positioned surrounding the second inner patterns, and the second outer pattern is rectangular frame shaped.

15. The method according to claim 14, wherein the second outer pattern does not contact each second inner pattern directly.

16. The method according to claim 10, wherein each outer pattern has two long edges and two short edges.

17. The method according to claim 16, wherein each long edge of each outer pattern is parallel to the first direction.
